(19) United States
(12) Patent Application Publication
(10) Pub. No.: US 2025/0044409 A1
(43) Pub. Date: Feb. 6, 2025

(54) SIGNAL PROCESSING METHOD, CORRESPONDING CIRCUIT, DEVICE, RADAR SYSTEM AND VEHICLE

(71) Applicant: STMicroelectronics International N.V., Geneva (CH)

(72) Inventors: Giuseppe PAPOTTO, Biancavilla (CT) (IT); Alessandro PARISI, Catania (IT); Giuseppe PALMISANO, S. Giovanni La Punta (CT) (IT)

(73) Assignee: STMicroelectronics International N.V., Geneva (CH)

(21) Appl. No.: 18/792,205

(22) Filed: Aug. 1, 2024

(30) Foreign Application Priority Data
Aug. 4, 2023 (IT) 102023000016764

(51) Int. Cl. G01S 7/35; G01S 7/03; G01S 13/931

(52) U.S. Cl. CPC G01S 7/358; G01S 7/032; G01S 13/931

(57) ABSTRACT

First signal processing is applied to a first input signal oscillating at an input frequency and a first set of control signals to generate a first output signal oscillating at a multiple of the input frequency with an amplitude controlled by a control signal in the first set of control signals. Second signal processing is applied to a second input signal oscillating in quadrature at the input frequency and a second set of control signals to generate a second output signal that oscillates at the multiple of the input frequency with an amplitude controlled by a control signal in the second set of control signals. A further output signal, generated in response to the first and second output signals, oscillates at the multiple of the input frequency with a phase shift controlled by a ratio of control signal amplitudes for the first and second sets of control signals.

### PRIORITY CLAIM

This application claims the priority benefit of Italian Application for Patent No. 102023000016764 filed on Aug. 4, 2023, the content of which is hereby incorporated by reference in its entirety to the maximum extent allowable by law.

### TECHNICAL FIELD

The description relates to circuits and systems for providing radio-frequency (RF) signals, such as frequency multiplier circuitry, for instance. One or more embodiments may be applied, e.g., in automotive radar applications.

### BACKGROUND

Increasingly higher demand for driving safety standards has led to a widespread adoption of an Advanced Driver Assistance System (ADAS) in the automotive field.

An ADAS implements control systems which may exploit several sensors, e.g., radar sensors, to provide functionalities such as adaptive cruise control, collision-avoidance, park assist, for instance.

A vehicle may comprise a plurality of radar sensors to facilitate detecting position and speed of objects nearby. For instance, the radar sensors may operate by transmitting a signal, e.g., millimeter-wave (1 millimeter=1 mm=10⁻³ m) signal (77 GHz according to ETSI standard, where 1 GHZ=1 GigaHertz=10⁹ Hz), and receiving an echo signal, reflected by the object nearby.

In a radar operating at the mm-wave range, a resonator-based approach (i.e., LC tank) facilitates to reduce power consumption in generating the signals to transmit.

At the same time, beam-scanning resolution is a figure of merit of radar systems, for instance for those configured to be equipped on-board autonomous driving vehicles.

In order to provide high beam-scanning resolution, the phase shifting accuracy of a phase-shifter becomes relevant in the signal processing chain of the radar system.

Phase shifters are mainly classified into active and passive phase shifter.

Passive phase shifters employ variable physical delay based on switchable filters or a tunable transmission line.

Reference is made to the following documents (all of which are incorporated by reference):
(1) M. Jung, et al., “A Compact Ka-Band 4-bit Phase Shifter With Low Group Delay Deviation,” IEEE Microwave and Wireless Components Letters, vol. 30, no. 4, pp. 414-416, April 2020, doi: 10.1109/LMWC.2020.2975108, which discusses a compact Ka-band 4-bit switch-type phase shifter with low group delay deviation (GDD) using 28-nm CMOS technology, wherein a magnetically coupled all-pass network (APN) configuration is employed to achieve both equal and flat group delay characteristics versus frequency at each phase state;
(2) W. H. Woods, et al., “CMOS millimeter wave phase shifter based on tunable transmission lines,” Proceedings of the IEEE 2013 Custom Integrated Circuits Conference, San Jose, CA, USA, 2013, pp. 1-4, doi: 10.1109/CICC.2013.6658442, which discusses a tunable transmission line (t-line) structure, featuring independent control of line inductance and capacitance. The t-line provides variable delay while maintaining relatively constant characteristic impedance using direct digital control through FET switches, where a 50 GHz RF-phase shifter for phased-array applications is implemented in a 32 nm SOI process attaining state-of-the-art performance; and
(3) S. Kishimoto, et al., “A 79GHz 13.5 dBm P sat at 150° C. transmitter with compact local phase shifter in 40 nm CMOS for automotive radar,” Proc. IEEE 20th Topical Meeting Silicon Monolithic Integr. Circuits RF Syst. (SiRF), pp. 66-69, 2020, which discusses a passive phase shifter in which the output phase can be changed by adjusting the impedance of a reflective load.

Active phase shifters comprise a vector modulator configured to provide a variable output phase by performing a (e.g., weighed) sum of orthogonal I/Q signals, wherein the phase of the output signal can be changed by adjusting a gain of variable gain amplifiers in the processing chain.

Reference is made to the following documents (all of which are incorporated by reference):
(4) Shimura, Toshihiro et al. “A 76-81 GHz active phase shifter for phased array automotive radar in 65 nm CMOS,” 2013 European Microwave Integrated Circuit Conference (2013): 252-255, which discusses an active phase shifter in 65 nm CMOS for phased array radar systems, covering dual radar bands of 76 GHz and 79 GHz, which achieves 360-degree phase variation using a vector combining method. 4-phase quadrature signals are produced using a coupled-line type 90-degree hybrid circuit and two single-to-differential amplifiers designed with a neutralization technique for stability and gain enhancement in wider frequency range;
(5) F. Akbar, et al., “A frequency tunable 350° analog CMOS phase shifter with an adjustable amplitude,” IEEE Transactions on Circuits and Systems II: Express Briefs, vol. 64, no. 12, pp. 1427-1431 December 2017, doi: 10.1109/TCSII.2017.2766662, which discusses a vector sum phase shifter topology utilizing a current mode R-C poly phase filter along with several current steering variable gain amplifiers, in which the phase shifter can generate a signal with a tunable phase and magnitude in a phased array, thereby providing a better control over the beamwidth and sidelobe levels; and

(6) B. Dou, et al., “A 4-10 GHz Programmable CMOS Vector-Sum Phase Shifter for a Two-Channel Transmitter,” IEEE Transactions on Circuits and Systems II: Express Briefs, vol. 69, no. 9, pp. 3699-3703 September 2022, doi: 10.1109/TCSII.2022.3173042, which discusses a 6-bit full-span programmable vector-sum phase shifter, in which a transformer-based matching network is used to match the PPF-based I/Q generator to the variable gain amplifier-based vector-modulator (VGA-based VM), which eliminates the performance degradation due to impedance mismatch, and where the proposed phase shifter integrated in a two-channel transmitter implemented in a 180-nm CMOS process.

Conventional phase shifters suffer one or more of the following drawbacks: limited capability to reduce the phase error while operating in the mm-wave range; active phase shifter show a limited robustness to PVT variations; passive phase shifters involve an increased area footprint on chip, and both passive and active phase shifter present a non-negligible power consumption.

There is a need in the art to contribute in overcoming one or more limits of current technology.

### SUMMARY

One or more embodiments may relate to a method.

One or more embodiments may relate to a corresponding circuit.

One or more embodiments may relate to a corresponding device.

One or more embodiments may relate to a corresponding system.

For instance, a radar system equipped onboard a vehicle may be exemplary of such a system.

One or more embodiments envisage a phase shifter comprising an embedded frequency multiplier functionality.

One or more embodiments facilitate reducing both silicon area occupation and power consumption.

In one or more embodiments, a phase-locked loop and/or other circuit elements are operated at a fraction of the frequency to counter frequency pulling from the power amplifier. This may also relax circuit design constraints and power consumption.

One or more embodiments provide a phase shifter capable to simultaneously performing phase shifting and frequency multiplication operations.

For example, the proposed phase shifter provides an Nth-harmonic of an input signal as an output signal while applying thereto a variable phase shifting (e.g., from 0° to) 360° controlled via a bias current.

In one or more embodiments, the phase shifting operation is independent from the input voltage amplitude and/or the supply voltage, leading to extending circuit robustness over process-voltage-temperature (PVT) variations.

### BRIEF DESCRIPTION OF THE DRAWINGS

One or more embodiments will now be described, by way of non-limiting example only, with reference to the annexed Figures, wherein:

FIG. 1 is a diagram exemplary of a method;

FIG. 2 is a diagram exemplary of a circuit;

FIGS. 3A, 3B and 3C are diagrams exemplary of frequency multiplication principles underlying one or more embodiments;

FIGS. 4A, 4B, 4C and 4D are diagrams exemplary of phase shifting principles underlying one or more embodiments;

FIG. 5 is a diagram exemplary of a circuit;

FIGS. 6 and 7 are diagrams exemplary of phase and amplitude of signals in one or more embodiments; and

FIG. 8 is a diagram exemplary of a radar system equipped onboard a vehicle.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The references used herein are provided merely for convenience and hence do not define the extent of protection or the scope of the embodiments.

For the sake of simplicity, in the following detailed description a same reference symbol may be used to designate both a node/line in a circuit and a signal which may occur at that node or line.

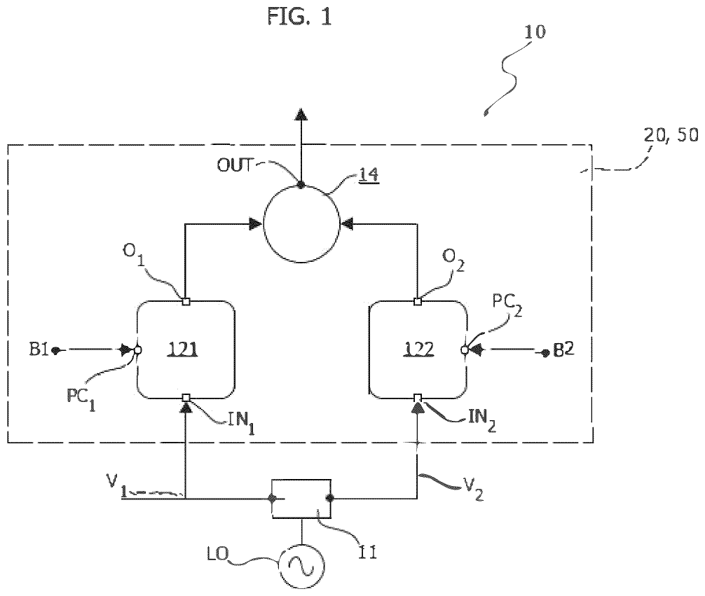

As exemplified in FIG. 1, a device 10 as per the present disclosure comprises: a radio-frequency RF signal generator configured to produce a first radio-frequency signal V₁ having a first signal frequency f₀; and a quadrature generator 11 configured to provide a second radio-frequency signal V₂ as an anteversion of the first radio-frequency signal V₁. In other words, the second input signal V₂ is in quadrature (that is, shifted by) 90° with the first input signal V₁.

For instance, the first V₁ and second V₂ input signals can be expressed as:

$${V}_{1} = A \cdot sin ( 2 π {f}_{0} )$$

$${V}_{2} = A \cdot cos ( 2 π {f}_{0} )$$

As exemplified in FIG. 1, the device 10 further comprises signal processing circuitry 20, 50 comprising a first frequency converter circuit 121 comprising a first input node IN₁ coupled to the RF signal generator and configured to receive the first input signal V₁ therefrom, the first frequency converter circuit 121 further comprising a first control node PC₁ configured to receive a first set of control signals B₁ (e.g., a first biasing current signal) and a first output node O₁ configured to provide an output signal whose output signal frequency and phase are based on the first input signal V₁ and the amplitude/intensity on the first set of control signals B₁, as discussed in the following. The first frequency converter circuit 121 further comprises a second frequency converter circuit 122 comprising a second input node IN₂ coupled to the RF signal generator and configured to receive the second input signal V₂ therefrom, the second frequency converter circuit 122 further comprising a second control node PC₂ configured to receive a second set of control signals B₂ (e.g., a second biasing current signal) and a second output node O₂ configured to provide an output signal whose output signal frequency and phase are based on the second input signal V₂ and the amplitude/intensity on the second set of control signals B₂, as discussed in the following. An output circuit block 14 (e.g., such as a resonant circuit LC tuned at a harmonic of the input signal frequency f₀) is coupled to the first 121 and second 122 frequency converter circuits to receive the first O₁ and second O₂ output signals therefrom (e.g., output current signals I_{O1}, I_{O2}) and configured to apply signal combination (e.g., superposition or subtraction) thereto, providing a frequency multiplied and phase shifted signal OUT to user circuits.

For instance, the first and second sets of control signals B₁, B₂ have different (e.g., signal intensity) values. For instance, the phase shift introduced by the device 10 on the output signal OUT varies (e.g., linearly) as a function of the ratio of the control signal B₁, B₂.

For instance, a first output signal O₁ produced by the first frequency converter circuit 121 and a second output signal O₂ produced by the second frequency converter circuit 122 can be expressed as:

$${O}_{1} = {B}_{1} \cdot sin ( 2 π {Nf}_{0} )$$

$${O}_{2} = {B}_{2} \cdot cos ( 2 π {Nf}_{0} )$$

where N is the frequency multiplication factor.

For instance, the further output signal OUT produced by the output circuit block 14 as a result of combining (e.g., superimposing or subtracting) the output signals O₁, O₂ can be expressed as:

$$OUT = B \cdot sin ( 2 π {Nf}_{0} + θ )$$

where B is the root mean square of the control signals B₁ and B₂, (i.e., \sqrt{B₁²+B₂²}) and θ is a phase-shift of the output signal.

For the sake of simplicity, one or more embodiments are discussed herein mainly with reference to switches comprising n-channel MOSFET switches, being otherwise understood that such a type of switch is purely exemplary and in no way limiting. One or more embodiments may employ p-channel MOSFET or BJT or virtually any other type of transistor switch known per se.

A method as exemplified herein comprises: receiving IN₁ a first input signal V₁oscillating at an input frequency f₀; receiving PC₁ a first set of control signals B₁; receiving IN₂ a second input signal V₂ oscillating at the input frequency and in quadrature with the first input signal; receiving PC₂ a second set of control signals B₂; applying first signal processing 121, 521 to the first input signal and to control signals in the first set of control signals, providing a first output signal O₁ as a result, the first output signal oscillating at an output frequency based on the input frequency and having an output signal amplitude based on the amplitude of at least one first control signal I_{B1} in the first set of control signals; applying second signal processing 122, 522 to the second input signal and to control signals in the second set of control signals, providing a second output signal O₂ as a result, the second output signal oscillating at a second output frequency equal to the first output frequency and having an output signal amplitude based on the amplitude of at least one second control signal I_{B2} in the second set of control signals; and based on the first output signal and the second output signal, providing 14 a further output signal OUT oscillating at an output signal frequency equal to the first output frequency and having a phase shift based on a ratio of signal amplitudes of at least one control signal in said first set of control signals and of at least one control signal in said second set of control signals.

As exemplified herein, control signals in the first B₁ and second B₂ set of control signals comprise biasing current signals I_{B1}, I_{B2} and the further output signal OUT has a phase shift θ based on a ratio of current intensities of at least one biasing current signal in said first set of control signals and of at least one biasing current signal in said second set of control signals.

A circuit 20, 50 as exemplified herein comprises: a first set of input nodes IN₁₁, IN₂₁; IN₂₃, IN₁₄ configured to receive a first input signal V₁ oscillating at an input frequency f₀; a first set of control nodes PC₁; PC₁₂, PC₃₄ configured to receive a first set of control signals B₁; a second set of input nodes IN₁₂, IN₂₂; IN₃₂, IN₄₁ configured to receive a second input signal V₂ oscillating at the input frequency and in quadrature with the first input signal; a second set of control nodes PC₂; PC₂₁, PC₃₄ configured to receive a second set of control signals B₂; and signal processing circuitry 121, 122; 521, 522 coupled to the first set of input nodes, to the first set of control nodes, to the second set of input nodes and to the second set of control nodes and having a further output circuit block 14; wherein the signal processing circuitry is configured to provide a further output signal OUT at said further output node according to the method as exemplified herein, the further output signal oscillating at an output signal frequency equal to the first output frequency and having a phase shift based on a ratio of signal amplitudes of at least one first control signal in said first set of control signals and of at least one second control signal in said second set of control signals.

The circuit 20; 50 as exemplified herein can be included in a device 10 further comprising a frequency synthesizer LO, 11 coupled to the circuit and configured to provide thereto the input signals oscillating at the input frequency.

For instance, the frequency synthesizer LO, 11 is configured to provide said input signals oscillating at the input frequency such that the output frequency of the further signal lies in the millimeter wavelength range.

A system as exemplified herein comprises: a device 10 as per the present disclosure; a power amplifier 180 coupled to the circuit and configured to receive the further output signal OUT therefrom, the power amplifier configured to amplify the further output signal and to provide an amplified output signal TX as a result, and a transmitter antenna 20 coupled to the power amplifier and configured to transmit the amplified output signal. For instance, the system includes a vehicular radar system.

As exemplified herein, a vehicle V can be equipped with a vehicular radar system comprising: a receiver antenna 22 configured to receive an echo signal based on the transmitted amplified output signal; and a mixer stage 28 coupled to the circuit as per the present disclosure, the mixer stage configured to apply frequency mixing to the further output signal and to the echo signal, producing a mixed signal as a result.

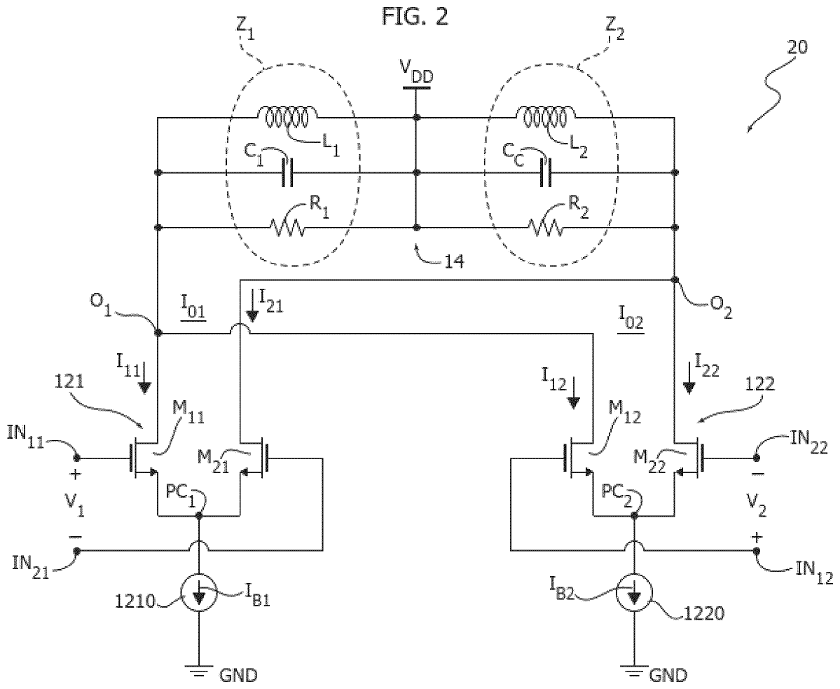

In a first exemplary scenario illustrated in FIG. 2, signal processing circuitry 20 as per the present disclosure comprises a first (e.g., fully) differential pair of switches M₁₁, M₂₁ comprising a first (e.g., n-channel MOSFET) switch M₁₁ and a second (e.g., n-channel MOSFET) switch M₂₁ configured to have the first input signal V₁ applied among switch control nodes IN₁₁, IN₂₁ and coupled to a first biasing (e.g., current) signal generator 1210 referred to ground GND to receive a first biasing (e.g., current) signal I_{B1} therefrom, the first differential pair of switches M₁₁, M₂₁ configured to provide a differential output signal among differential output nodes O₁, O₂; for instance, the first switch M₁₁ has a first control node IN₁₁, a first output node O₁ and a first source node PC₁ coupled to a second source node of a second switch M₂₁ which has a respective second control node IN₂₁ and second output node O₂. The signal processing circuitry 20 further comprises a second (e.g., fully) differential pair of switches M₁₂, M₂₂ comprising a third (e.g., n-channel MOSFET) switch M₁₂ and a fourth (e.g., n-channel MOSFET) switch M₂₂ configured to have the second input signal V₂ applied among switch control nodes IN₁₂, IN₂₂ and coupled to a second biasing (e.g., current) signal generator 1220 referred to ground GND to receive a second biasing (e.g., current) signal I_{B2} therefrom, the second differential pair of switches M₁₂, M₂₂ configured to provide a differential output signal among differential output nodes O₁, O₂; for instance, the third switch M₁₂ has a third control node IN₁₂, a third output node and a third source node PC₂ coupled to a fourth source node of the fourth switch M₂₂ which has a respective fourth control node IN₂₂ and fourth output node.

As exemplified in FIG. 2, the first output node O₁ of the first differential pair M₁₁, M₂₁ is coupled to the third output node of the second differential pair M₁₂, M₂₂ while the second output node O₂ of the first differential pair M₁₁, M₂₁ is coupled to the fourth output node of the second differential pair M₁₂, M₂₂.

As exemplified in FIG. 2, the first 121 and second 122 frequency converter circuits are coupled to a set of load circuits Z₁, Z₂ comprising: a first load circuit Z₁ comprising a first RLC network, e.g., comprising a first resistive element R₁ in parallel to a first capacitive element C₁ and to a first inductive element L₁; and a second load circuit Z₂ comprising a second RLC network, e.g., comprising a second resistive element R₂ in parallel to a second capacitive element C₂ and to a second inductive element L₂.

As exemplified in FIG. 2, the load circuits Z₁, Z₂ are coupled to a biasing node VDD configured to provide a supply voltage VDD and have a circuit output nodes O₁, O₂ configured to provide an output signal OUT as a combination (e.g., superposition) of the differential output signals I_{O1}, I_{O2} provided by the frequency converter circuits 121, 122, the output signal OUT having a frequency based on (e.g., multiple of) the input frequency f₀ of the input signals V₁, V₂.

In order to do so, the passive electrical components L₁, C₁ and L₂, C₂ in the first Z₁ and second Z₂ load circuits are tuned at a desired N-th harmonic of the input signal frequency f₀, based on the relation between resonant frequency and capacitance/inductance which may be expressed as ω=1/\sqrt{LC}.

As exemplified in FIG. 2, the intensities I_{O1}, 1_{O2} of electrical currents generated by the current generators 1210, 1220 may be varied by the user depending on the application. For instance, setting different intensity values for the electrical currents I_{O1}, I_{O2} introduces a phase difference between signals output from the first frequency converter circuit 121 and the second frequency converter circuit 122, as discussed in the following.

For instance, the phase shift is a result of the combination (e.g., superposition or difference) at the output circuit block 14 (e.g., implemented via the resonant loads Z₁, Z₂) of the output current signals produced by each differential circuit 121, 122.

A method of driving the circuit 20 as per the present disclosure comprises: driving the first differential pair M₁₁, M₂₁ by applying the first input signal V₁ at the control nodes IN₁₁, IN₂₁ of the first differential pair M₁₁, M₂₁, alternatively making conductive a current flow path through the first switch M₁₁ while making non-conductive a current flow path through the second switch M₂₁; and driving the second differential pair M₁₂, M₂₂ by applying the second input signal V₂ (which is in quadrature with the first input signal V₁) at the control nodes IN₁₂, IN₂₂ of the second differential pair M₁₂, M₂₂, alternatively making conductive a current flow path through the fourth switch M₂₂ while making non-conductive a current flow path through the third switch M₁₂.

As a result, the first biasing current signal I_{B1} generated by the first current generator 1210 and the second biasing current signal I_{B2} generated by the second current generator 1220 are each multiplied by a square wave of unitary amplitude.

Therefore, a first output current signal I_{O1} comprises a square wave output comprising odd harmonics of the first input signal V₁.

$${I}_{o 1} = {I}_{11} - {I}_{21} = \frac{4}{π} [ sin ( {ω}_{0} t ) + \frac{1}{3} sin ( 3 {ω}_{0} t ) + \frac{1}{5} sin ( 5 {ω}_{0} t ) + ⋯ + \frac{1}{( 2 N + 1 )} sin ( ( 2 N + 1 ) {ω}_{0} t ) ] \cdot {I}_{B 1}$$

where I_{B1} is the biasing current provided by the first current generator 1210.

Similarly, a second output current signal I_{O2} comprises a square wave output comprising odd harmonics of the second input signal V₂ and can be expressed as:

$${I}_{o 2} = {I}_{12} - {I}_{22} = \frac{4}{π} [ cos ( {ω}_{0} t ) + \frac{1}{3} cos ( 3 {ω}_{0} t ) + \frac{1}{5} cos ( 5 {ω}_{0} t ) + ⋯ + \frac{1}{( 2 N + 1 )} cos ( ( 2 N + 1 ) {ω}_{0} t ) ] \cdot {I}_{B 2}$$

As exemplified in FIG. 2, the LC resonant loads Z1, Z2 filter the undesired (odd) harmonics.

As exemplified in FIGS. 1 and 2, a frequency multiplier circuit 10, 50 having an odd multiplication factor of (2N+1) can be obtained by tuning the LC resonant load Z₁, Z₂ at the (2N+1)-th off harmonics of the input signal V₁, which may be expressed as:

$${I}_{oi} = {I}_{o 1 i} - {I}_{o 2 i} = \frac{4}{π} [ \frac{1}{2 N + 1} sin ( ( 2 N + 1 ) {ω}_{0} t ) ] \cdot {I}_{{B}_{}}$$

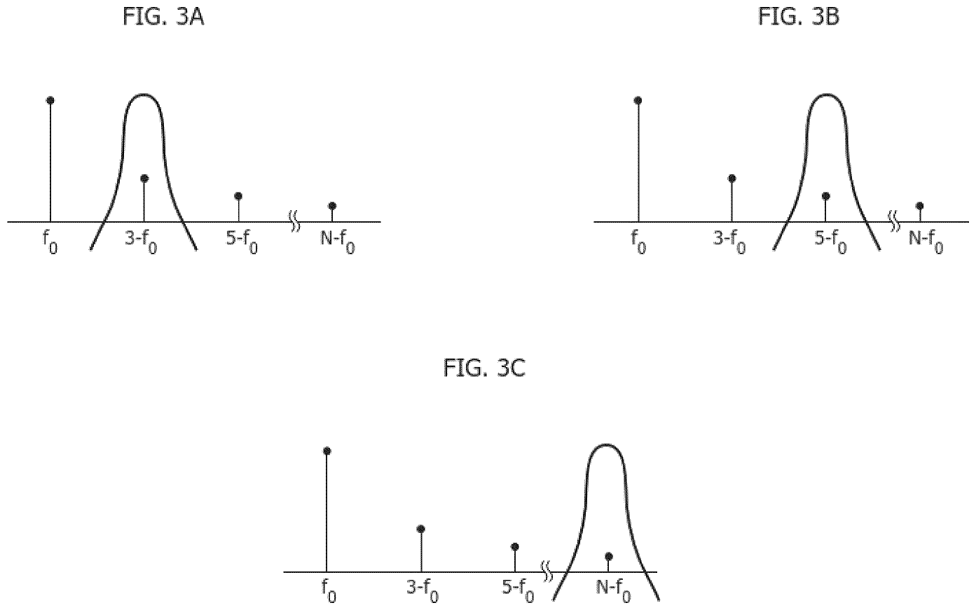

FIGS. 3A-3C are diagrams exemplary of a spectral content of the frequency multiplied signal at various multiples of the input signal frequency f₀.

For instance, a frequency multiplier circuit 10, 20 having multiplication factor of three can be obtained by tuning the LC resonator at the 3rd harmonics of the input signal Vi. In such an exemplary case, the i-th differential output signal I_{Oi} can be expressed as:

$${I}_{oi} = {I}_{o 1 i} - {I}_{o 2 i} = \frac{4}{π} [ \frac{1}{3} sin ( 3 {ω}_{0} t ) ] \cdot {I}_{{B}_{}}$$

For instance, if the input signal Vi has an input signal frequency f0 about 26 GHz, a multiplier circuit 20 with multiplication factor of 3 can provide an output signal OUT having an output signal frequency f_{OUT} about 78 GHz.

FIG. 3A is a diagram exemplary of a spectral content of the frequency multiplied signal at frequency multiple three times the input signal frequency f₀.

In a further exemplary scenario, a frequency multiplier by five is obtained by tuning the LC resonator at the 5th harmonic of the input signal Vi. In such an exemplary case, the i-th differential output signal I_{O1} can be expressed as:

$${I}_{oi} = {I}_{o 1 i} - {I}_{o 2 i} = \frac{4}{π} [ \frac{1}{5} sin ( 5 {ω}_{0} t ) ] \cdot {I}_{{B}_{}}$$

FIG. 3B is a diagram exemplary of a spectral content of the frequency multiplied signal at frequency multiple five times the input signal frequency f₀.

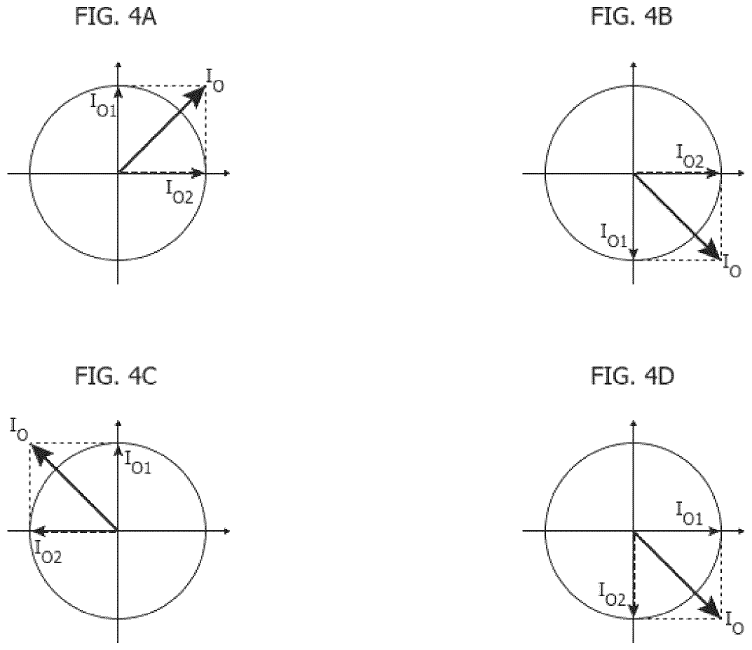

As exemplified in FIGS. 4A-4B, a differential output current of the two circuit cells which receive input signals V_{1,} V₂ in quadrature therebetween comprises of sum of two orthogonal vectors I_{O1}, I_{O2} whose intensities can be modulated by changing the biasing currents I_{B1}, I_{B2} provided by the respective biasing current generators 1210, 1220.

For instance, the current intensities of output signals I_{O1}, I_{O2} may be expressed as:

$${I}_{o 1} = {I}_{o 11} - {I}_{o 21} = \frac{4}{π} [ \frac{1}{N} sin ( ( 2 N + 1 ) {ω}_{0} t ) ] \cdot {I}_{B 1}$$

$${I}_{o 2} = {I}_{o 12} - {I}_{o 22} = \frac{4}{π} [ \frac{1}{N} cos ( ( 2 N + 1 ) {ω}_{0} t ) ] \cdot {I}_{B 2}$$

A current intensity of the output current signal I_{O} can be expressed as a sum of the output current signals I_{O1}, I_{O2}, such as:

$${I}_{o 1} = {I}_{o 1} + {I}_{o 2} = \frac{4}{π N} [ sin ( ( 2 N + 1 ) {ω}_{0} t ) \cdot {I}_{B 1} + cos ( ( 2 N + 1 ) {ω}_{0} t ) \cdot {I}_{B 2} ]$$

As exemplified in FIGS. 1 and 2, an output voltage signal OUT is equal to a differential voltage at nodes O1 and O2. As exemplified in FIG. 2, an output voltage can be expressed as OUT=Io×R where Io is the output current and R may be expressed as R=R1+R2, in case the resonant networks L₁C₁ and L₂C₂ resonate at a frequency f which is an odd multiple of the input frequency f0, namely f=(2N+1)*fo.

As exemplified herein, a method of operating the circuit 10, 20 comprises performing phase shifting based on differential output signals I_{O1}, I_{O2} output by respective circuit units 121, 122. For instance, a sum current I_{O} (which may be expressed as I_{O}=I_{O1}+I_{O2}) is based on the sum of two vectors IO1, IO2 in quadrature therebetween and having different amplitudes/intensity, thereby varying the phase-shift of the sum signal OUT, I_{O}.

For instance, performing phase shifting comprises setting the ratio of intensities of biasing currents I_{B1}, I_{B2} produced by biasing generators 1211, 1221 to have a ratio equal to the tangent of a phase shift angle θ providing a linear phase shift of the sum signal OUT, I_{O} based on differential output signals I_{O1}, I_{O2} as a result.

As exemplified in FIG. 4A, if the phase shift θ to introduce falls in a range 0° to 90°, a ratio of biasing current intensities can be expressed as:

$$tan θ = \frac{{I}_{B 1}}{{I}_{B 2}}$$

In other words, the phase shift θ of the output signal OUT resulting from a differential voltage signal based on the first output signal O₁ and the second output signal O₂ is based on a ratio of the signal amplitudes of control signals (e.g., equal to current intensities in case of biasing current signals), which can be expressed as:

$$θ = arctan ( \frac{{I}_{B 1}}{{I}_{B 2}} )$$

where arctan is an inverse function of the trigonometric tangent function.

In such an exemplary scenario, a first intensity I_{B1} of the biasing current generated by the first biasing current generator 1211 can be expressed as:

$${I}_{B 1} = {I}_{B} \cdot cos θ$$

Still in the exemplary scenario considered, a second intensity I_{B2} of the biasing current generated by the second biasing current generator 1211 can be expressed as:

$${I}_{B 2} = {I}_{B} \cdot sin θ$$

As a result, the output current signal has an output current intensity I_{O} which can be expressed as:

$${I}_{o 1} = {I}_{o 1} - {I}_{o 2} = \frac{4 {I}_{B}}{π ( 2 N + 1 )} [ sin ( ( 2 N + 1 ) {ω}_{0} t ) \cdot cos θ + cos ( ( 2 N + 1 ) {ω}_{0} t ) \cdot sin θ ]$$

Exploiting trigonometric equivalence, the output current intensity I_{O} of the output signal OUT can be expressed as:

$${I}_{o} = \frac{4 {I}_{B}}{π ( 2 N + 1 )} sin ( ( 2 N + 1 ) {ω}_{0} t + θ )$$

A circuit and method as exemplified facilitate an increased robustness over PVT variations thanks to the use of the biasing current to vary the phase shift.

An arrangement as exemplified in FIG. 2 facilitates varying the phase shift θ of the output signal OUT within at least one quadrant of the turn angle.

It may be possible to vary the phase shift also in the entire turn angle, that is in a range of linear phase shift angle values from 0° to 360°, for instance by changing sign and amplitude of biasing currents I_{B1}, I_{B2}.

FIGS. 4B to 4D are diagrams exemplary of a way of representing the total current I_{O}as a vector whose orientation in a complex plane is a function of the first and second output signals I_{O1}, I_{O2}, whose relative orientation varies as a function of the biasing current values I_{B1}, I_{B2}, as discussed in the foregoing.

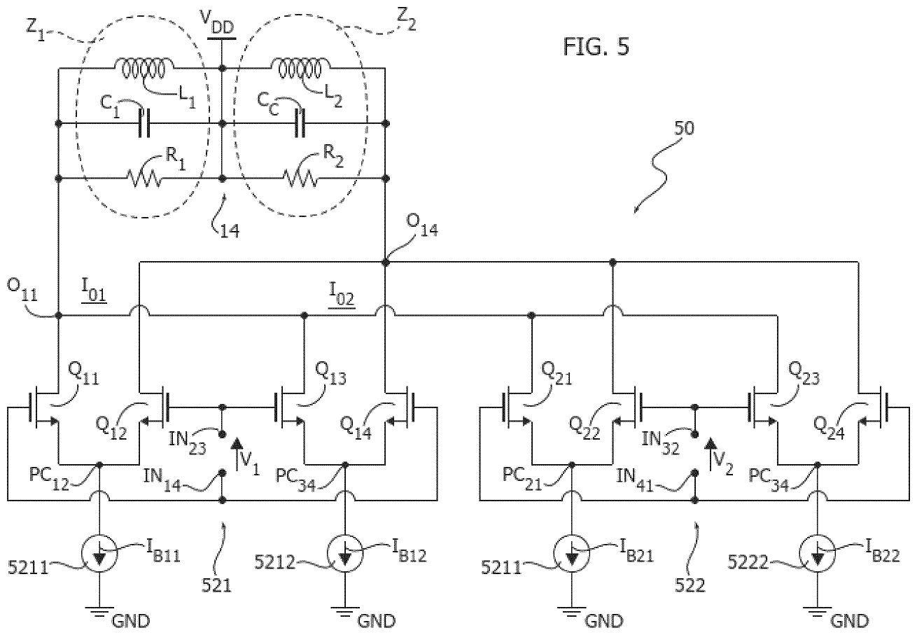

In an alternative scenario exemplified in FIG. 5, an alternative circuit 50 for use in the device 10 comprises, in place of the first frequency converter circuit 121 and the second frequency converter circuit 122 in the circuit 20 exemplified in FIG. 2: a first alternative (e.g., double-balanced) frequency converter circuit 521 comprising a Gilbert-cell like arrangement comprising two (pairs of) differential pairs of (e.g., n-channel MOSFET) switches Q₁₁, Q₁₂, Q₁₃, Q₁₄, each replicating the arrangement of the first differential pair M₁₁, M₂₁ exemplified in FIG. 2 save for the way in which the control nodes of the switches are driven, as discussed in the following; and a second alternative (e.g., double-balanced) frequency converter circuit 522 comprising a further Gilbert-cell like arrangement comprising two further (pairs of) differential pairs of (e.g., n-channel MOSFET) switches Q₂₁, Q₂₂, Q₂₃, Q₂₄, each replicating the arrangement of the second differential pair M₁₂, M₂₂ exemplified in FIG. 2 save for the way in which the control nodes of the switches are driven, as discussed in the following.

As exemplified in FIG. 5, the first alternative frequency converter circuit 521 comprises: a first differential pair of switches Q₁₁, Q₁₂ comprising a first switch Qu having a control node IN₁₄ coupled to the respective control node of a fourth switch Q14 and a first biasing node PC₁₂ coupled to the respective biasing node of a second switch Q₁₂ having a control node IN₂₃ coupled to a respective control node of a third switch Q₁₃; and a second differential pair of switches Q₁₃, Q₁₄ comprising the third switch Q₁₃ having the control node IN₂₃ coupled to the control node of the second switch Q₁₂ in the first differential pair Q₁₁, Q₁₂ and a second biasing node PC₃₄ coupled to the biasing node of the fourth switch Q₁₄ having the control node IN₁₄ coupled to the respective control node of the first switch Q₁₁ in the first differential pair Q₁₁, Q₁₂. A first biasing current generator 5211 is coupled to the first biasing node PC₁₂ of the first differential pair Q₁₁, Q₁₂ to provide a first biasing current I_{B11} thereto, and a second biasing current generator 5212 coupled to the second biasing node PC₃₄ of the second differential pair Q₁₃, Q₁₄ to provide a second biasing current I_{B22} thereto.

As exemplified in FIG. 5, the second alternative frequency converter circuit 522 comprises: a third differential pair of switches Q₂₁, Q₂₂ comprising a fifth switch Q₂₁ having a control node IN₄₁ coupled to the respective control node of an eight switch Q₂₄ and a third biasing node PC₂₁ coupled to the respective biasing node of a sixth switch Q₂₂ having a control node IN₃₂ coupled to a respective control node IN₃₂ of a seventh switch Q₂₃; and a fourth differential pair of switches Q₂₃, Q₂₄ comprising the seventh switch Q₂₃ having the control node IN₃₂ coupled to respective control node IN₃₂ of the sixth switch Q₂₂ in the third differential pair Q₂₁, Q₂₂ and a fourth biasing node PC₃₄ coupled to the biasing node of the eight switch Q₂₄ having the control node IN₄₁ coupled to the respective control node IN₄₁ of the fifth switch Q₂₁ in the third differential pair Q₂₁, Q₂₂. A third biasing current generator 5221 coupled to the third biasing node PC₂₁ of the third differential pair Q₂₁, Q₂₂ to provide a third biasing current I_{B21} thereto, and a fourth biasing current generator 5222 coupled to the fourth biasing node PC₃₄ of the fourth differential pair Q₂₃, Q₂₄ to provide a fourth biasing current I_{B22} thereto.

As exemplified in FIG. 5, a method of operating the circuit 50 comprises: applying a first input signal V₁ among the control nodes IN₂₃, IN₁₄ of the first alternative frequency converter circuit 521; applying a second input signal V₂ (is in quadrature with the first input signal V₁) among the control nodes IN₃₂, IN₄₁ of the second alternative frequency converter circuit 522; and setting the current intensity values I_{B11}, I_{B12}, I_{B21}, I_{B22} of biasing currents generated via the first, second, third and fourth biasing current generators 5211, 5212, 5221, 5222 to produce a phase shift of the output signal.

The alternative circuit 50 exemplified in FIG. 5 with respect to the circuit 20 exemplified in FIG. 2 facilitates further increasing robustness versus PVT variations thanks to the possibility to have some current generators deactivated in varying the phase shift in a range of linear phase shift angle values 0° to 360°.

For instance, the current intensities I_{B11}, I_{B12}, I_{B21}, I_{B22} for different ranges of phase shift values θ may be expressed as:

$$θ ∈ [ 0 ° , 90 ° ] ↔ {I}_{B 12} = {I}_{B 22} = 0 ; {I}_{B 11} = {I}_{B} \cdot cos θ ; {I}_{B 21} = {I}_{B} \cdot sin θ$$

$$θ ∈ [ 90 ° , 180 ° ] ↔ {I}_{B 12} = {I}_{B 21} = 0 ; {I}_{B 11} = {I}_{B} \cdot cos θ ; {I}_{B 22} = {I}_{B} \cdot sin θ$$

$$θ ∈ [ 180 ° , 270 ° ] ↔ {I}_{B 11} = {I}_{B 21} = 0 ; {I}_{B 12} = {I}_{B} \cdot cos θ ; {I}_{B 22} = {I}_{B} \cdot sin θ$$

$$θ ∈ [ 270 ° , 360 ° ] ↔ {I}_{B 11} = {I}_{B 22} = 0 ; {I}_{B 12} = {I}_{B} \cdot cos θ ; {I}_{B 21} = {I}_{B} \cdot sin θ$$

In other words, based on intensity values of at least one further control signal I_{B11}, I_{B12}, I_{B21}, I_{B22} and at least one control signal I_{B1}, I_{B2} being based on the biasing phase shift value θ it is possible to alternately apply the input voltages V₁, V₂, with alternating phases to the differential input nodes IN1, IN2 of the circuit 20, 50. Without being bound to a specific theoretical model, this can be the result of turning alternatively ON and OFF transistors in the differential pairs of transistors as a result of setting at least two control signals at zero intensity/amplitude.

In variant embodiments, it may be possible to vary the four current intensity values I_{B11}, I_{B12}, I_{B21}, I_{B22} as a function of the two parameters β₁, β₂ with respect to their sum I_{B}.

For instance, in such an alternative scenario the biasing current intensity values I_{B11},

I_{B12}, I_{B21}, I_{B22} can be expressed as:

$${I}_{B 11} = {I}_{B} - {β}_{1} ; {I}_{B 12} = {I}_{B} + {β}_{1} ; {I}_{B 21} = {I}_{B} - {β}_{2} ; {I}_{B 22} = {I}_{B} + {β}_{2}$$

where the considerations expressed in the foregoing with reference to FIGS. 4A-4D can be applied likewise to determine the values of the parameters β₁, β₂.

In the considered variant embodiments, to extend the range of applicable phase shift θ to at least two quadrants of the turn angle, the values of current intensity parameter β₁, β₂ may be expressed as:

$$θ ∈ [ 0 ° , 90 ° ] ↔ {β}_{1} = \frac{{I}_{B}}{α} \cdot cos θ ; {β}_{2} = \frac{{I}_{B}}{α} \cdot sin θ$$

$$θ ∈ [ 90 ° , 180 ° ] ↔ {β}_{1} = \frac{{I}_{B}}{α} \cdot cos θ ; {β}_{2} = - \frac{{I}_{B}}{α} \cdot sin θ$$

$$θ ∈ [ 180 ° , 270 ° ] ↔ {β}_{1} = - \frac{{I}_{B}}{α} \cdot cos θ ; {β}_{2} = - \frac{{I}_{B}}{α} \cdot sin θ$$

$$θ ∈ [ 270 ° , 360 ° ] ↔ {β}_{1} = - \frac{{I}_{B}}{α} \cdot cos θ ; {β}_{2} = \frac{{I}_{B}}{α} \cdot sin θ$$

where α is a user settable parameter whose value is greater than unity or one.

The circuits 20, 50 as exemplified herein can be integrated circuits, for instance integrated in a 28 nm FD-SOI CMOS technology (per se known).

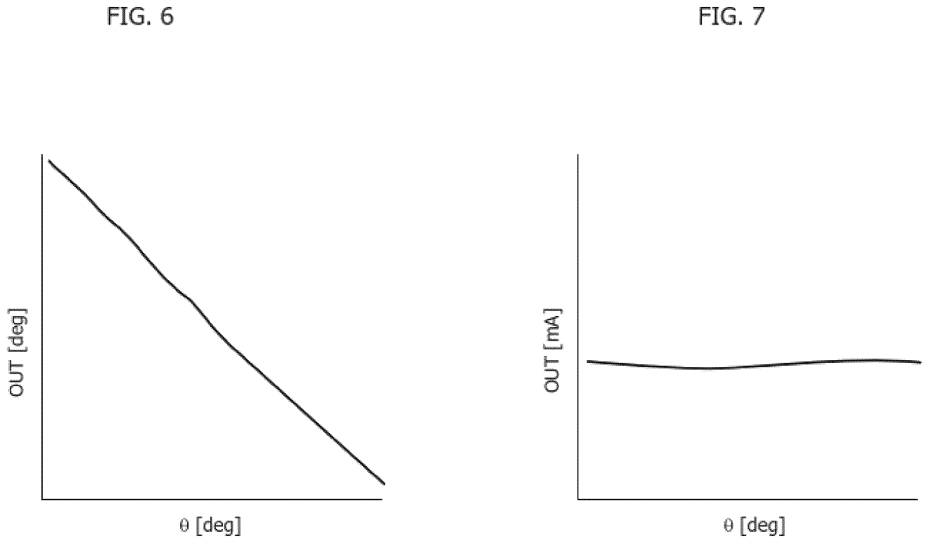

FIG. 6 shows a plot of the phase of the output signal OUT provided by the circuits 10, 20, 50 as a function of the phase shift θ which is indicative of the linear type relationship among the two parameters.

FIG. 7 shows a plot of amplitude of the output signal OUT provided by the device 10 comprising the circuit 20 or 50 as a function of the phase shift θ, which is indicative of the fact that the amplitude of the signal remains substantially constant during phase-shift variations.

In a method as exemplified herein, providing 14 the further output signal OUT comprises: providing at least one resonant network stage R₁, L₁, C₁; R₂, C₂, L₂ and tuning the at least one (resonant) network stage to resonate at an odd integer multiple of the input frequency f₀ of the first, resp. second, input signal V₁, V₂; and applying resonant filtering Z₁, Z₂ to a signal based on the first O₁ and the second O₂ amplified difference signals, producing the further output (e.g., voltage) signal OUT as a result.

In a first exemplary scenario exemplified in FIG. 2, applying said first signal processing 121; 521 and said second signal processing 122; 522 comprises: providing a first signal amplification processing stage M₁₁, M₂₁; Q₁₁, Q₁₂, Q₁₃, Q₁₄ and a second signal amplification processing stage M_{12,} M₂₂; Q₂₁, Q₂₂, Q₂₃, Q₂₄, the first, resp. second, signal amplification processing stage comprising at least one differential pair of transistors having current flow paths therethrough configured to be made selectively conductive and non-conductive based on the first, resp. second, input signal and having a common biasing node therebetween; coupling, to the first signal amplification processing stage, a first set of current generators 1210; 5211, 5212 configured to provide the first set of control signals; and coupling, to the second signal amplification processing stage, a first set of current generators 1220; 5221, 5222 configured to provide the second set of control signals.

As exemplified herein, the method comprises: coupling at least one resonant network stage to the first and to the second signal amplification processing stages; tuning the at least one network stage to resonate at an odd integer multiple of the input frequency of the first, resp. second, input signal; and applying resonant filtering to a difference among the first and the second amplified difference signals, producing the further output signal as a result; wherein the further output signal comprises a voltage signal.

For instance, the method comprises varying said phase shift θ within at least one quarter of the turn angle.

As exemplified herein: the first set of control signals B₁ comprises a first plurality of biasing current signals I_{B11}, I_{B12}; the second set of control signals B₂ comprises a second plurality of biasing current signal I_{B21}, I_{B22}; and at least one biasing current signal in first plurality of biasing current signals and at least one biasing current signal in the second plurality of biasing current signal is equal to zero.

As exemplified herein: the first set of control signals B₁ comprises a first biasing current signal I_{B11} and a second biasing current signal I_{B12}; and the second set of control signals B₂ comprises a third biasing current signal I_{B21} and a fourth biasing current signal I_{B22}.

For instance: the first biasing current signal has a first biasing intensity equal to a common biasing I_{B} intensity plus a first biasing coefficient β₁; the second biasing current signal has a second biasing intensity equal to the common biasing intensity I_{B} minus the first biasing coefficient β₁; the third biasing current signal has a third biasing intensity equal to the common biasing intensity I_{B} plus a second biasing coefficient β₂; the fourth biasing current signal has a fourth biasing intensity equal to the common biasing intensity I_{B} minus the second biasing coefficient β₂; and said phase shift θ is equal to an arc-tangent of the ratio of the first biasing coefficient β₁ and the second biasing coefficient β₂.

As exemplified herein, said first biasing coefficient β₁ and said second biasing coefficient β₂ are based on a ratio of the common current intensity I_{B} and an integer value α greater than one.

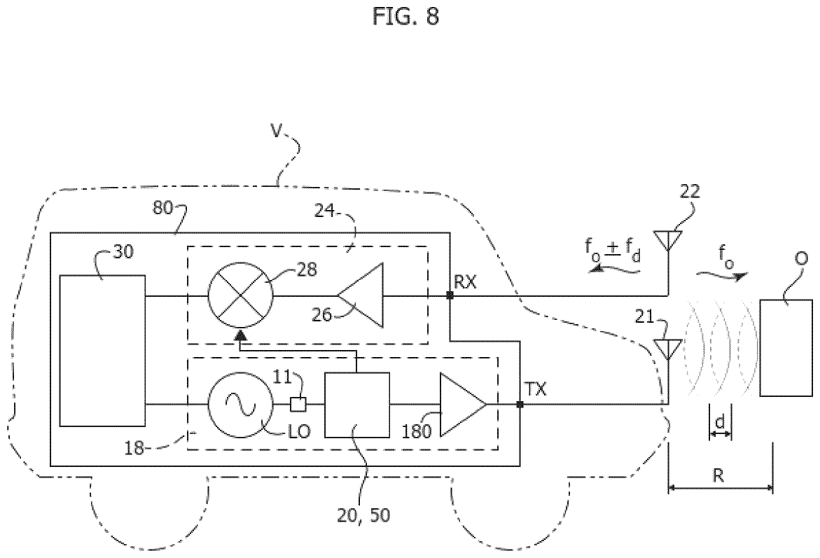

As exemplified in FIG. 8, a vehicle V can be equipped with a radar system 80 comprising a device 10 as per the present disclosure and antennas 21, 22 in order to detect an object O, for instance an obstacle along a traveling path of the vehicle V.

Distance R (and speed) of the object O can be detected by measuring a time delay d between a transmitted signal (whose wave-front is shown in solid lines) having a carrier signal frequency f₀ and the received echo signal (whose wave-front is shown in dashed lines) having a spectral content f₀±f_{d} spread over the carrier radio-frequency signal at frequency f₀.

As exemplified in FIG. 8, a radar transceiver system 80 comprises: a transmitter chain 18 configured to provide a RF signal to a transmitting antenna (e.g., array) 21; a receiver chain 24 configured to detect the echo signal reflected from the obstacle O via a receiver antenna (e.g., array) 22; and a processing system 30 configured to drive the transmission of signals from the transmitter chain 18 and to process signals detected by the receiver chain 24.

As exemplified in FIG. 8, the transmitter chain 18 comprises: a frequency synthesizer LO, such as a phase-locked loop (PLL) configured to generate the first input signal V₁configured to provide a sub-harmonic of the operating frequency, e.g., to counter frequency pulling from the power amplifier; a quadrature generator 11 coupled to the frequency synthesizer LO to provide the second input signal V₂ as an antiphase or quadrature version of the first input signal V₁; a circuit (implemented in the single 20 or double balanced 50 topologies, for instance) coupled to the frequency synthesizer LO and to the phase-shifter to receive the first V₁ and second V₂ input signals therefrom, the circuit 20, 50 configured to perform frequency multiplication and to apply a linear phase shift θ to the input signals V₁, V₂, providing as a result an output signal OUT which comprises an odd harmonic of the RF signal and has a phase shift θ which is a function of user-settable parameters B₁, B₂; and a (transmitter) amplifier 180, e.g., a variable-gain amplifier (VGA) or a power amplifier (PA), coupled to the circuit 20, 50 to receive the (odd) harmonic OUT of the RF signal V₁ therefrom, the amplifier 180 configured to amplify the harmonic of the RF signal produced via the circuit 20, 50 and to operate/drive the transmission (TX) antenna (array) 21 therewith.

As exemplified in FIG. 8, the corresponding incoming (echo) signal received at a receiving (RX) antenna 22 is fed to the receiver chain 24, comprising: a low noise amplifier (LNA) 26, coupled to the receiver antenna (e.g., array) 22 to receive the echo signal therefrom; and a frequency converter stage 28 coupled to the LNA 26 to receive the detected echo signal therefrom and coupled to the PLL to receive the local oscillator signal LO therefrom, the frequency converter stage 28 configured to produce a down-converted frequency signal IF based on the echo signal and the LO signal, in a manner per se known.

In one or more embodiments, the radar system 80 may be a system-on-chip integrated in a semiconductor device. For instance, the proposed system can be integrated in a 28-nm FD-SOI CMOS technology device equipped on-board a transmitter stage of a mm-wave 77 GHz CMOS radar system.

It will be otherwise understood that the various individual implementing options exemplified throughout the figures accompanying this description are not necessarily intended to be adopted in the same combinations exemplified in the figures. One or more embodiments may thus adopt these (otherwise non-mandatory) options individually and/or in different combinations with respect to the combination exemplified in the accompanying figures.

The claims are an integral part of the technical teaching provided herein with reference to the embodiments.

Without prejudice to the underlying principles, the details and embodiments may vary, even significantly, with respect to what has been described by way of example only, without departing from the extent of protection. The extent of protection is defined by the annexed claims.

1. A method, comprising:
receiving a first input signal oscillating at an input frequency;
receiving a first set of control signals;
receiving a second input signal oscillating at the input frequency and in quadrature with the first input signal;
receiving a second set of control signals;
applying first signal processing to the first input signal and control signals in the first set of control signals to provide a first output signal oscillating at a first output frequency based on the input frequency and having an output signal amplitude based on an amplitude of at least one first control signal in the first set of control signals;
applying second signal processing to the second input signal and control signals in the second set control signals to provide a second output signal oscillating at a second output frequency equal to the first output frequency and having an output signal amplitude based on the amplitude of at least one second control signal in the second set of control signals;
generating, based on the first output signal and the second output signal, a further output signal oscillating at an output signal frequency equal to the first output frequency and having a phase shift controlled by a ratio of signal amplitudes of at least one control signal in said first set of control signals and at least one control signal in said second set of control signals.

2. The method of claim 1, wherein:
control signals in the first and second set of control signals comprise biasing current signals; and
the further output signal has a phase shift based on a ratio of current intensities of the biasing current signals in said first set of control signals and said second set of control signals.

3. The method of claim 1, wherein generating the further output signal comprises:
tuning at least one resonant network stage to resonate at an odd integer multiple of the input frequency of the first and second input signals; and
applying resonant filtering to a signal based on the first output signal and the second output signal to produce the output voltage signal.

4. The method of claim 1, wherein applying said first signal processing and said second signal processing comprises:
providing a first signal amplification processing stage and a second signal amplification processing stage, each of the first and second signal amplification processing stages comprising at least one differential pair of transistors having current flow paths therethrough configured to be made selectively conductive and non-conductive based on the first, respectively second, input signal and having a common biasing node therebetween;
coupling, to the first signal amplification processing stage, a first set of current generators configured to provide the first set of control signals;
coupling, to the second signal amplification processing stage, a second set of current generators configured to provide the second set of control signals.

5. The method of claim 4, comprising:
coupling at least one resonant network stage to the first and second signal amplification processing stages;
tuning the at least one resonant network stage to resonate at an odd integer multiple of the input frequency of the first and second input signals; and
applying resonant filtering to a difference among the first and second output signals to produce the output signal;
wherein the further output signal comprises a voltage signal.

6. The method of claim 1, further comprising varying said phase shift within at least one quarter of the turn angle.

7. The method of claim 1, wherein:
the first set of control signals comprises a first plurality of biasing current signals;
the second set of control signals comprises a second plurality of biasing current signals; and
at least one biasing current signal in first plurality of biasing current signals and at least one biasing current signal in the second plurality of biasing current signal is equal to zero.

8. The method of claim 1, wherein:
the first set of control signals comprises a first biasing current signal and a second biasing current signal;
the second set of control signals comprises a third biasing current signal and a fourth biasing current signal;
wherein:
the first biasing current signal has a first biasing intensity equal to a common biasing intensity plus a first biasing coefficient;
the second biasing current signal has a second biasing intensity equal to the common biasing intensity minus the first biasing coefficient;
the third biasing current signal has a third biasing intensity equal to the common biasing intensity plus a second biasing coefficient;
the fourth biasing current signal has a fourth biasing intensity equal to the common biasing intensity minus the second biasing coefficient;
said phase shift is equal to an arc-tangent of a ratio of the first biasing coefficient and the second biasing coefficient.

9. The method of claim 8, wherein said first biasing coefficient and said second biasing coefficient are based on a ratio of the common current intensity and an integer value greater than one.

10. A circuit, comprising:
a first set of input nodes configured to receive a first input signal oscillating at an input frequency;
a first set of control nodes configured to receive a first set of control signals;
a second set of input nodes configured to receive a second input signal oscillating at the input frequency and in quadrature with the first input signal;
a second set of control nodes configured to receive a second set of control signals; and
signal processing circuitry coupled to the first set of input nodes, to the first set of control nodes, to the second set of input nodes and to the second set of control nodes;
wherein the signal processing circuitry is configured to provide a further output signal, the further output signal oscillating at an output signal frequency and having a phase shift based on a ratio of signal amplitudes of at least one first control signal in said first set of control signals and at least one second control signal in said second set of control signals.

11. The circuit of claim 10, wherein:
control signals in the first and second set of control signals comprise biasing current signals; and
the further output signal has a phase shift based on a ratio of current intensities of the biasing current signals in said first set of control signals and said second set of control signals.

12. The circuit of claim 10, wherein said signal processing circuitry comprises:
a first circuit configured to generate a first output signal from the first input signal and first set of control signals;
a second circuit configured to generate a second output signal from the second input signal and second set of control signals;
at least one resonant network stage tuned to resonate at an odd integer multiple of the input frequency of the first and second input signals; and
wherein said at least one resonant network stage applies resonant filtering based on the first output signal and the second output signal to produce the output voltage signal.

13. The circuit of claim 11, wherein:
the first circuit comprises a first signal amplification processing stage and the second circuit comprises a second signal amplification processing stage;
each of the first and second signal amplification processing stages comprising at least one differential pair of transistors having current flow paths therethrough configured to be made selectively conductive and non-conductive based on the first, respectively second, input signal and having a common biasing node therebetween;
a first set of current generators configured to provide the first set of control signals is coupled to the first signal amplification processing stage; and
a second set of current generators configured to provide the second set of control signals is coupled to the second signal amplification processing stage.

14. The method of claim 13, wherein:
the at least one resonant network stage is coupled to the first and second signal amplification processing stages; and
the at least one resonant network stage is tuned to resonate at an odd integer multiple of the input frequency of the first and second input signals.

15. A device, comprising:
the circuit according to claim 10; and
a frequency synthesizer coupled to the circuit and configured to provide thereto the input signals oscillating at the input frequency.

16. The device according to claim 15, wherein the frequency synthesizer is configured to provide said input signals oscillating at the input frequency such that the output frequency of the further output signal lies in the millimeter wavelength range.

17. A system, comprising:
the device according to claim 15;
a power amplifier coupled to the circuit and configured to receive the further output signal therefrom, the power amplifier configured to amplify the further output signal and to provide an amplified output signal as a result, and
a transmitter antenna coupled to the power amplifier and configured to transmit the amplified output signal.

18. The system of claim 17, including a vehicular radar system comprising:
a receiver antenna configured to receive an echo signal based on the transmitted amplified output signal,
a mixer stage coupled to the circuit, the mixer stage configured to apply frequency mixing to further output signal and to the echo signal, producing a mixed signal as a result.

19. A vehicle equipped with a vehicular radar system according to claim 18.
